(19) United States
(12) Patent Application Publication
(10) Pub. No.: US 2023/0317680 A1
(43) Pub. Date: Oct. 5, 2023

(54) RIBBON SHIELD DEVICE AND METHOD

(71) Applicant: Intel Corporation, Santa Clara, CA (US)

(72) Inventors: Prabhat Ranjan, Bangalore (IN); Boon Ping Koh, Seberang Jaya 07 (MY); Min Suet Lim, Simpang Ampat (MY); Yew San Lim, Penang (MY); Ranjul Balakrishnan, Bangalore (IN); Omkar Karhade, Chandler, AZ (US); Robert A. Stingel, Gilbert, AZ (US); Nitin Deshpande, Chandler, AZ (US)

(21) Appl. No.: 17/707,340

(22) Filed: Mar. 29, 2022

(51) Int. Cl. H01L 25/065; H01L 23/00

(52) U.S. Cl. CPC H01L 25/0657; H01L 24/49; H01L 24/48; H01L 2225/06562; H01L 2225/0651; H01L 2224/49176; H01L 2224/48097; H01L 2224/85986

(57) ABSTRACT

An electronic device and associated methods are disclosed. In one example, the electronic device includes one or more ribbon bond connections along with one or more wire bond connections. In one example, ribbon bond connections are shown, and are coupled to ground, and configured to provide a shielding effect to wire bond connections.

### TECHNICAL FIELD

Embodiments described herein generally relate electronic devices, such as semiconductor devices. Some specific embodiments described relate to signal shielding technologies.

### BACKGROUND

In operation, wire bond connections may carry high speed data signals. As device sizes continually shrink, and data speeds continually increase, challenges such as adjacent wire bond crosstalk become more pronounced. It is desirable to reduce negative effects such as adjacent wire bond crosstalk and electromagnetic interference (EMI). Configurations described below address these, and other technical challenges related to wire bond connections.

### BRIEF DESCRIPTION OF THE DRAWINGS

FIG. 1 shows an electronic device in accordance with some example embodiments.

FIG. 2 shows an electronic device including a vertical ribbon bond in accordance with some example embodiments.

FIG. 3 shows a close up view of a vertical ribbon bond from FIG. 2 in accordance with some example embodiments.

FIG. 4 shows a cross section of interconnects in accordance with some example embodiments.

FIG. 5 shows a cross section of interconnects in accordance with some example embodiments.

FIG. 6 shows an electronic device including ribbon bonds in accordance with some example embodiments.

FIG. 7 shows a flow diagram of a method of manufacture of an electronic interconnect device in accordance with some example embodiments.

FIG. 8 shows a system that may incorporate an electronic interconnect device and methods, in accordance with some example embodiments.

### DESCRIPTION OF EMBODIMENTS

The following description and the drawings sufficiently illustrate specific embodiments to enable those skilled in the art to practice them. Other embodiments may incorporate structural, logical, electrical, process, and other changes. Portions and features of some embodiments may be included in, or substituted for, those of other embodiments. Embodiments set forth in the claims encompass all available equivalents of those claims.

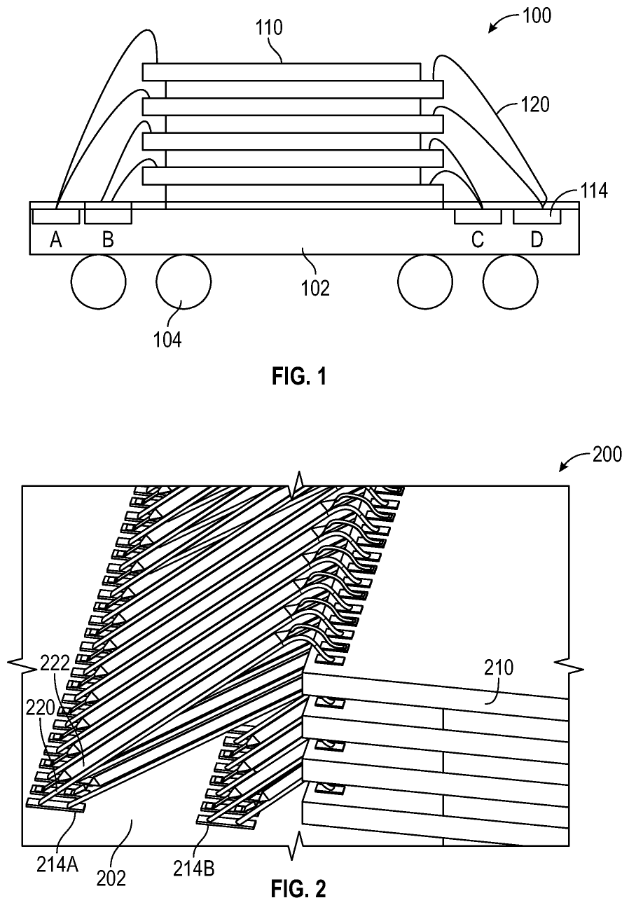

FIG. 1 shows an electronic device 100. In one example, the electronic device 100 includes a memory device. One or more semiconductor dies 110 are shown coupled to a substrate 102. The substrate 102 includes a number of solder bumps 104 that may be used to couple to a subsequent circuit board, such as a mother board (not shown). In the example of FIG. 1, a stack of memory dies 110 are shown in an offset configuration with the dies 110 being stacked with top edges of all dies 110 exposed. This offset configuration allows wire bonds to be attached to the exposed top surface portion of the dies 110 in the stack. In manufacturing of electronic devices such as device 100, wire bond connections are fast at transmitting electrical signals, and are relatively inexpensive to manufacture. They are also easy to program for different connection configurations as device layout designs may change. In the example of FIG. 1, four different channels 114 are shown as channel A, B, C, and D. One or more different dies 110 can be wire bonded to different channels 114. The use of multiple channels 114 allows each channel 114 to communicate with a selected number of dies 110 to best manage bandwidth and speed in communication. It is desirable to improve speed, reduce noise, and otherwise improve performance of communication between the channels 114 in the substrate 102, and the dies 110.

FIG. 2 shows an electronic device 200. In the example of FIG. 2, the electronic device 200 includes multiple memory dies 210 coupled to a substrate 202. Although memory dies are used as an example, the invention is not so limited. Other die types include, but are not limited to, processor dies, controller dies, mixed memory and processor dies, etc. In the example of FIG. 2, the dies 210 are offset from one another to permit top surface wire bonding. One example of an offset configuration is shown in FIG. 2, although the invention is not so limited. other examples of offset die stacking include single stair stepped stacks, multiple stair stepped stacks going in different directions, etc.

A first channel substrate terminal 214A and a second channel substrate terminal 214B are shown. A number of wire bond connections 220 are shown coupled from the dies 210 to the channel substrate terminals 214A, 214B. In the example shown, the number of wire bond connections 220 include two separate rows of wire bond connections 220 from two adjacent dies in the offset stack going to respective channel substrate terminals 214A, 214B. The invention is not, however, limited to any one channel configuration or to offset dies, or to multiple die stacks.

In operation, wire bond connections 220 may carry high speed data signals. As device sizes continually shrink, and data speeds continually increase, challenges such as adjacent wire bond crosstalk become more pronounced. It is desirable to reduce negative effects such as adjacent wire bond crosstalk.

FIG. 2 further shows one or more vertical ribbon bond connections 222 from a die 210 to the substrate 202. Ribbon bond connections include a flat cross section, with a thickness and a width that is wider than the thickness. In one example, a ribbon bond connection is formed by extruding a round cross section wire bond from a die, then rolling the round wire bond into a flattened cross section. In another example, a ribbon bond is extruded from a flat cross section die. In manufacturing, a robotic arm is used to locate an end of wire bond or ribbon bond connections, and the robotic arm moves from one end of a connection to another while extruding material to form the connections. In one example, a rotation axis on the robotic arm is added to allow a ribbon bond connection to be twisted as described in more detail below.

A ribbon bond connection can be oriented a number of ways. In one orientation, a width dimension is generally parallel to a major plane of the substrate 202. This orientation can be defined as a horizontal ribbon bond. In another orientation, the width dimension can lie within a plane that is orthogonal to the major plane of the substrate 202. This orientation can be defined as a vertical ribbon bond. In one example, a ribbon bond connection may include some portions along a ribbon bond length that are horizontal, and some portions that are vertical. In one example, it is useful from a manufacturing standpoint to attach a ribbon bond connection to a surface such as a substrate 202 or a die 210 in a horizontal orientation, then to twist, or otherwise reorient a middle portion of a ribbon bond connection.

As noted above, FIG. 2 further shows one or more vertical ribbon bond connections 222 from a die 210 to the substrate 202. In one example, a vertical ribbon bond connection 222 is defined as vertical due to a majority of the connection 222 being vertical. In one example, a vertical ribbon bond connection 222 is defined as vertical due to a presence of any one portion of the connection 222 being vertical.

In one example, one or more vertical ribbon bond connections 222 are coupled to ground voltage and serve as shielding structures. Other voltages apart from ground are also within the scope of the invention. In the example shown, a vertical ribbon bond connection 222 is located between at least two wire bond connections 220. In one example, one or more vertical ribbon bond connections 222 are interspersed within a row of wire bond connections 220 from a die 210 to the substrate 202. In one example, a vertical ribbon bond connections 222 is interspersed as alternating between every wire bond connection 220 from the die 210 to the substrate 202. As shown in FIG. 2, vertical ribbon bond connections 222 can be interspersed within rows of wire bond connections 220 on multiple levels of a stack of dies 210 and to multiple channels 214A, 214B.

The presence of the vertical ribbon bond connection 222 at ground voltage provides at least some shielding effect, and reduces crosstalk noise, and/or provides some electromagnetic interference (EMI) protection. Because the vertical ribbon bond connection 222 is flat and vertical, it provides a greater shielding effect than if it were a single wire with a round cross section.

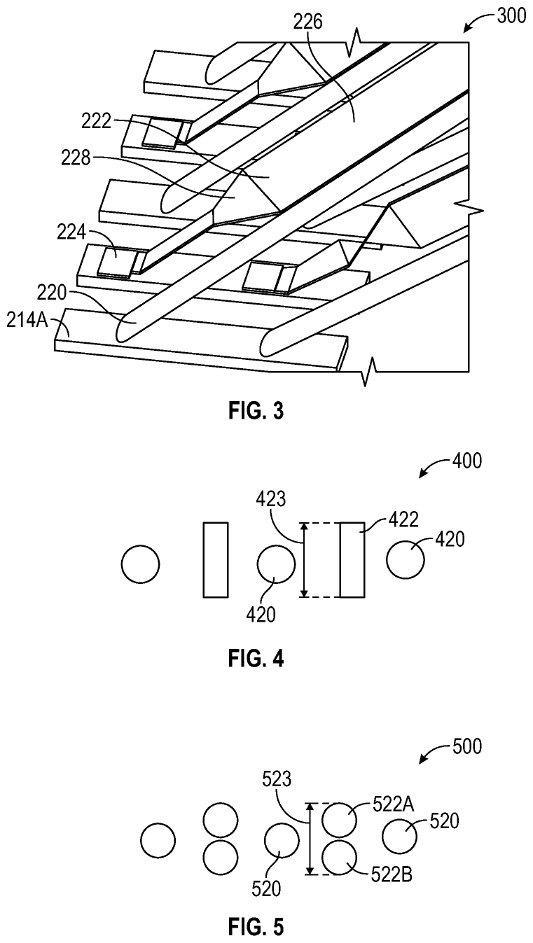

FIG. 3 shows a close up view of the channel substrate terminal 214A. A vertical ribbon bond connection 222 is shown between two wire bond connections 220. In the example of FIG. 3, the vertical ribbon bond connection 222 includes a horizontal portion 224 and a vertical portion 226 with a twist 228 that transitions between the two portions 224, 226. As noted above, in some examples, it is advantageous to manufacture a vertical ribbon bond connection 222 by twisting to provide both a robust bonding attachment at the channel substrate terminal 214A, and to provide good shielding properties along the vertical portion 226 between the two wire bond connections 220.

FIG. 4 shows a block diagram of cross sections of wire bond connections 420 and vertical ribbon bond connections 422. A width dimension 423 is shown that is larger than a diameter of the wire bond connections 420. The larger width 423 provide increased shielding effects as discussed above.

FIG. 5 shows a block diagram of another configuration with cross sections of wire bond connections 520. In FIG. 5, a vertical group of wire bond connections 522A and 522B are shown. As in other examples, the vertical group of wire bond connections 522A and 522B can be coupled to ground voltage. The vertical group of wire bond connections 522A and 522B acts like a vertical ribbon bond connection, and provides an increased width 523. In one example, similar to vertical ribbon bond connections, the vertical group of wire bond connections 522A and 522B both lie in a vertical plane that is oriented orthogonal to a major plane of a substrate. As with the example of FIG. 4, a width dimension 523 is larger than a diameter of the wire bond connections 520. The larger width 523 provide increased shielding effects as discussed above.

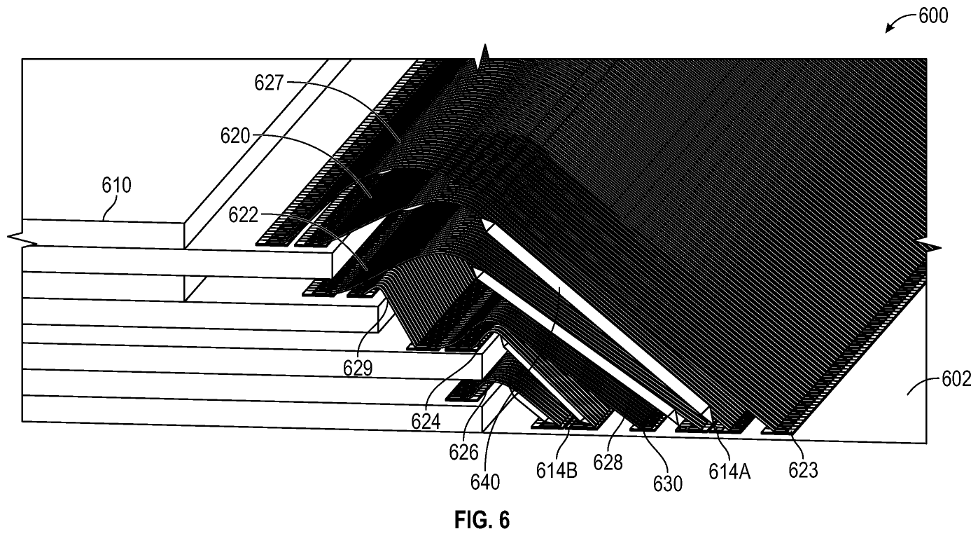

FIG. 6 shows an electronic device 600. In the example of FIG. 6, the electronic device 600 includes a stack of offset memory dies 610 coupled to a substrate 602. In the example of FIG. 6, the dies 610 are offset from one another to permit top surface wire bonding. FIG. 6 shows one example of an offset stacking configuration that includes stair stepping.

A first channel substrate terminal 614A and a second channel substrate terminal 614B are shown. Multiple rows of wire bond connections 620, 622, 624, 626 are shown coupled from multiple dies 610 in the stack of offset semiconductor dies to the substrate to the channel substrate terminals 614A, 614B.

FIG. 6 further shows a row of ribbon bond connections 627 from a die 610 in the stack of offset semiconductor dies to the substrate, wherein the row of ribbon bond connections 627 is vertically adjacent to at least one row of wire bond connections from the multiple rows of wire bond connections. In one example, the row of ribbon bond connections 627 includes horizontal ribbon bond connections 627 as described above.

In one example, the at least one row of ribbon bond connections 627 are coupled to ground voltage at terminal 623 and serve as shielding structures. Other voltages apart from ground are also within the scope of the invention. In one example, the inclusion of at least one row of ribbon bond connections 627 provides at least some shielding effect, and reduces crosstalk noise, and/or provides some electromagnetic interference (EMI) protection. Because the row of ribbon bond connections 627 is flat and horizontal, it provides a greater shielding effect from above and below than if it were a single wire with a round cross section.

FIG. 6 further shows a second row of ribbon bond connections 628. In one example, the second row of ribbon bond connections 628 are also coupled to ground at terminal 630, and provide a shielding effect. In the example shown, the second row of ribbon bond connections 628 is between two different channels in the stack of offset semiconductor dies. The rows of wire bond connections 620 and 622 are coupled to channel substrate terminals 614A, while the rows of wire bond connections 624 and 626 are coupled to channel substrate terminals 614B. The second row of ribbon bond connections 628 in between the rows of wire bond connections coupled to the different channels 614 and 614B.

In one example, at least one row of wire bond connections (620, 622, 624, 626) is bounded by a row of ribbon bond connections from above and below. For example, at least one row of wire bond connections (one or more of 620, 622) is bounded by the row of ribbon bond connections 627 from above and by the second row of ribbon bond connections 628 from below.

In one example, a row of ribbon bond connections vertically separates two rows of the multiple rows of wire bond connections. For example, in FIG. 6, row of ribbon bond connections 628 vertically separates row of wire bond connections 627 from row of wire bond connections 624. In one example, two or more cascades of ribbon bond connections are electrically coupled together, and vertically separate two rows of the multiple rows of wire bond connections. For example, in FIG. 6, two cascades of ribbon bond connections 628 and 629 are electrically coupled together to a ground voltage. The two cascades of ribbon bond connections 628 and 629 electrically separate row of wire bond connections 627 from row of wire bond connections 624.

FIG. 6 further shows one example that includes one or more vertical ribbon bond connections 640 as described in examples above. In one example, one or more vertical ribbon bond connections 640 are located on an edge of at least one row of wire bond connections. As shown in FIG. 6, in one example, at least one row of wire bond connections 620 is bounded by rows of ribbon bond connections 627, 628 from above and below, and further bounded on sides by vertical ribbon bond connections 640.

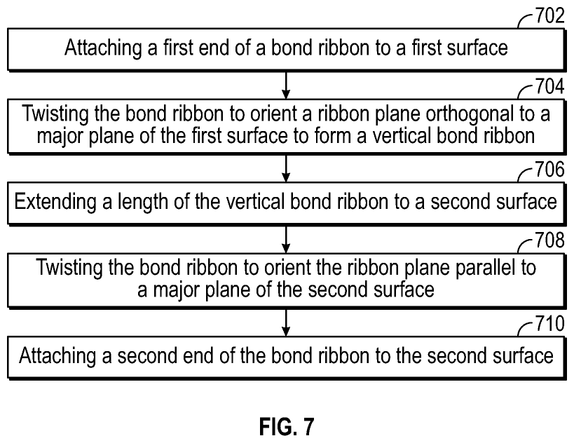

FIG. 7 shows a flow diagram of an example method of manufacture. As noted above, a ribbon bonding head may be attached to a robotic arm that is capable of twisting a ribbon orientation. In operation 702, a first end of a bond ribbon is attached to a first surface. In operation 704, the bond ribbon is twisted to orient a ribbon plane orthogonal to a major plane of the first surface to form a vertical bond ribbon. In operation 706, a length of the vertical bond ribbon is extended to a second surface. In operation 708, the bond ribbon is twisted to orient the ribbon plane parallel to a major plane of the second surface, and in operation 710, a second end of the bond ribbon is attached to the second surface.

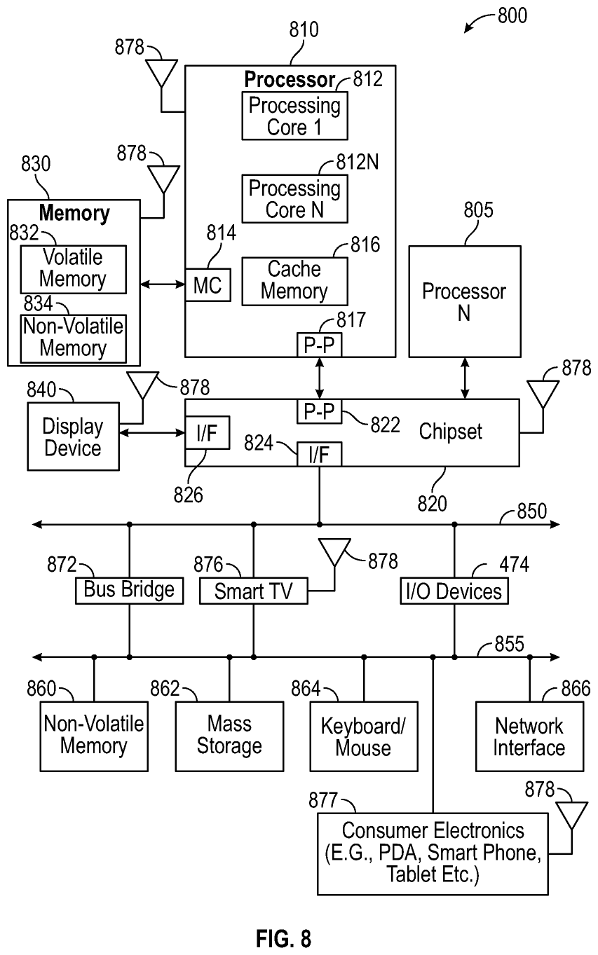

FIG. 8 illustrates a system level diagram, depicting an example of an electronic device (e.g., system) that may include vertical ribbon bond connections, rows of ribbon bonds, and methods described above. In one embodiment, system 800 includes, but is not limited to, a desktop computer, a laptop computer, a netbook, a tablet, a notebook computer, a personal digital assistant (PDA), a server, a workstation, a cellular telephone, a mobile computing device, a smart phone, an Internet appliance or any other type of computing device. In some embodiments, system 800 includes a system on a chip (SOC) system.

In one embodiment, processor 810 has one or more processor cores 812 and 812N, where 812N represents the Nth processor core inside processor 810 where N is a positive integer. In one embodiment, system 800 includes multiple processors including 810 and 805, where processor 805 has logic similar or identical to the logic of processor 810. In some embodiments, processing core 812 includes, but is not limited to, pre-fetch logic to fetch instructions, decode logic to decode the instructions, execution logic to execute instructions and the like. In some embodiments, processor 810 has a cache memory 816 to cache instructions and/or data for system 800. Cache memory 816 may be organized into a hierarchal structure including one or more levels of cache memory.

In some embodiments, processor 810 includes a memory controller 814, which is operable to perform functions that enable the processor 810 to access and communicate with memory 830 that includes a volatile memory 832 and/or a non-volatile memory 834. In some embodiments, processor 810 is coupled with memory 830 and chipset 820. Processor 810 may also be coupled to a wireless antenna 878 to communicate with any device configured to transmit and/or receive wireless signals. In one embodiment, an interface for wireless antenna 878 operates in accordance with, but is not limited to, the IEEE 802.11 standard and its related family, Home Plug AV (HPAV), Ultra Wide Band (UWB), Bluetooth, WiMax, or any form of wireless communication protocol.

In some embodiments, volatile memory 832 includes, but is not limited to, Synchronous Dynamic Random Access Memory (SDRAM), Dynamic Random Access Memory (DRAM), RAMBUS Dynamic Random Access Memory (RDRAM), and/or any other type of random access memory device. Non-volatile memory 834 includes, but is not limited to, flash memory, phase change memory (PCM), read-only memory (ROM), electrically erasable programmable read-only memory (EEPROM), or any other type of non-volatile memory device.

Memory 830 stores information and instructions to be executed by processor 810. In one embodiment, memory 830 may also store temporary variables or other intermediate information while processor 810 is executing instructions. In the illustrated embodiment, chipset 820 connects with processor 810 via Point-to-Point (PtP or P-P) interfaces 817 and 822. Chipset 820 enables processor 810 to connect to other elements in system 800. In some embodiments of the example system, interfaces 817 and 822 operate in accordance with a PtP communication protocol such as the Intel® QuickPath Interconnect (QPI) or the like. In other embodiments, a different interconnect may be used.

In some embodiments, chipset 820 is operable to communicate with processor 810, 805N, display device 840, and other devices, including a bus bridge 872, a smart TV 876, I/O devices 874, nonvolatile memory 860, a storage medium (such as one or more mass storage devices) 862, a keyboard/mouse 864, a network interface 866, and various forms of consumer electronics 877 (such as a PDA, smart phone, tablet etc.), etc. In one embodiment, chipset 820 couples with these devices through an interface 824. Chipset 820 may also be coupled to a wireless antenna 878 to communicate with any device configured to transmit and/or receive wireless signals. In one example, any combination of components in a chipset may be separated by a continuous flexible shield as described in the present disclosure.

Chipset 820 connects to display device 840 via interface 826. Display 840 may be, for example, a liquid crystal display (LCD), a light emitting diode (LED) array, an organic light emitting diode (OLED) array, or any other form of visual display device. In some embodiments of the example system, processor 810 and chipset 820 are merged into a single SOC. In addition, chipset 820 connects to one or more buses 850 and 855 that interconnect various system elements, such as I/O devices 874, nonvolatile memory 860, storage medium 862, a keyboard/mouse 864, and network interface 866. Buses 850 and 855 may be interconnected together via a bus bridge 872.

In one embodiment, mass storage device 862 includes, but is not limited to, a solid state drive, a hard disk drive, a universal serial bus flash memory drive, or any other form of computer data storage medium. In one embodiment, network interface 866 is implemented by any type of well-known network interface standard including, but not limited to, an Ethernet interface, a universal serial bus (USB) interface, a Peripheral Component Interconnect (PCI) Express interface, a wireless interface and/or any other suitable type of interface. In one embodiment, the wireless interface operates in accordance with, but is not limited to, the IEEE 802.11 standard and its related family, Home Plug AV (HPAV), Ultra Wide Band (UWB), Bluetooth, WiMax, or any form of wireless communication protocol.

While the modules shown in FIG. 8 are depicted as separate blocks within the system 800, the functions performed by some of these blocks may be integrated within a single semiconductor circuit or may be implemented using two or more separate integrated circuits. For example, although cache memory 816 is depicted as a separate block within processor 810, cache memory 816 (or selected aspects of 816) can be incorporated into processor core 812.

To better illustrate the method and apparatuses disclosed herein, a non-limiting list of embodiments is provided here:

Example 1 includes an electronic device. The electronic device includes a semiconductor die coupled to a substrate, one or more wire bond connections from the semiconductor die to the substrate, and one or more vertical ribbon bond connections from the semiconductor die to the substrate, wherein at least a portion of the one or more vertical ribbon bond connections is oriented with a ribbon plane orthogonal to a major plane of the substrate.

Example 2 includes the electronic device of example 1, wherein the one or more vertical ribbon bond connections is coupled to a ground voltage when in operation.

Example 3 includes the electronic device of any one of examples 1-2, wherein the one or more vertical ribbon bond connections includes a twist to translate a portion of the vertical ribbon bond connection from horizontal to vertical.

Example 4 includes the electronic device of any one of examples 1-3, wherein the one or more vertical ribbon bond connections are interspersed within a row of wire bond connections from the semiconductor die to the substrate.

Example 5 includes the electronic device of any one of examples 1-4, wherein vertical ribbon bond connections are included alternating between data signal wires within a row of wire bond connections from the semiconductor die to the substrate.

Example 6 includes the electronic device of any one of examples 1-5, wherein the semiconductor die includes a memory die.

Example 7 includes the electronic device of any one of examples 1-6, wherein the semiconductor die is a memory die included within a stack of memory dies.

Example 8 includes the electronic device of any one of examples 1-7, wherein vertical ribbon bond connections are included alternating between data signal wires within multiple rows of wire bond connections between different level dies in the stack of memory dies and the substrate.

Example 9 includes an electronic device. The electronic device includes a stack of offset semiconductor dies coupled to a substrate, multiple rows of wire bond connections from multiple dies in the stack of offset semiconductor dies to the substrate, and a row of ribbon bond connections from a die in the stack of offset semiconductor dies to the substrate, wherein the row of ribbon bond connections is vertically adjacent to at least one row of wire bond connections from the multiple rows of wire bond connections.

Example 10 includes the electronic device of example 9, wherein the row of ribbon bond connections is between two different channels in the stack of offset semiconductor dies.

Example 11 includes the electronic device of any one of examples 9-10, wherein the row of ribbon bond connections is coupled to a ground voltage when in operation.

Example 12 includes the electronic device of any one of examples 9-11, wherein the row of ribbon bond connections vertically separates two rows of the multiple rows of wire bond connections.

Example 13 includes the electronic device of any one of examples 9-12, wherein two or more cascades of ribbon bond connections are electrically coupled together, and vertically separate two rows of the multiple rows of wire bond connections.

Example 14 includes the electronic device of any one of examples 9-13, further including one or more vertical ribbon bond connections from the semiconductor die to the substrate, wherein at least a portion of the one or more vertical ribbon bond connections is oriented with a ribbon plane orthogonal to a major plane of the substrate.

Example 15 includes the electronic device of any one of examples 9-14, wherein the vertical ribbon bond connection is on an edge of at least one row of wire bond connections from the multiple rows of wire bond connections.

Example 16 includes the electronic device of any one of examples 9-15, wherein at least one row of wire bond connections from the multiple rows of wire bond connections is bounded by a row of ribbon bond connections from above and below, and wherein the at least one row of wire bond connections from the multiple rows of wire bond connections is bounded on sides by vertical ribbon bond connections.

Example 17 includes a method that includes attaching a first end of a bond ribbon to a first surface, twisting the bond ribbon to orient a ribbon plane orthogonal to a major plane of the first surface to form a vertical bond ribbon, extending a length of the vertical bond ribbon to a second surface, twisting the bond ribbon to orient the ribbon plane parallel to a major plane of the second surface, and attaching a second end of the bond ribbon to the second surface.

Example 18 includes the method of example 17, further including coupling the vertical bond ribbon to a ground voltage when in operation.

Example 19 includes the method of any one of examples 17-18, further including coupling the vertical bond ribbon laterally between two data signal bond wires.

Example 20 includes the method of any one of examples 17-19, further including coupling the vertical bond ribbon at a lateral edge of a row of wire bond connections, the row of wire bond connections coupled between a die and a substrate.

Example 21 includes the method of any one of examples 17-20, further including coupling a row of ribbon bond connections vertically adjacent to the row of wire bond connections.

Example 22 includes an electronic device. The electronic device includes a semiconductor die coupled to a substrate, two data wire bond connections from the semiconductor die to the substrate, and a ground voltage vertical group of wire bond connections from the semiconductor die to the substrate, wherein the vertical group of wire bond connections both lie in a vertical plane that is oriented orthogonal to a major plane of the substrate, and wherein the vertical group of wire bond connections is between the two data wire bond connections.

Throughout this specification, plural instances may implement components, operations, or structures described as a single instance. Although individual operations of one or more methods are illustrated and described as separate operations, one or more of the individual operations may be performed concurrently, and nothing requires that the operations be performed in the order illustrated. Structures and functionality presented as separate components in example configurations may be implemented as a combined structure or component. Similarly, structures and functionality presented as a single component may be implemented as separate components. These and other variations, modifications, additions, and improvements fall within the scope of the subject matter herein.

Although an overview of the inventive subject matter has been described with reference to specific example embodiments, various modifications and changes may be made to these embodiments without departing from the broader scope of embodiments of the present disclosure. Such embodiments of the inventive subject matter may be referred to herein, individually or collectively, by the term “invention” merely for convenience and without intending to voluntarily limit the scope of this application to any single disclosure or inventive concept if more than one is, in fact, disclosed.

The embodiments illustrated herein are described in sufficient detail to enable those skilled in the art to practice the teachings disclosed. Other embodiments may be used and derived therefrom, such that structural and logical substitutions and changes may be made without departing from the scope of this disclosure. The Detailed Description, therefore, is not to be taken in a limiting sense, and the scope of various embodiments is defined only by the appended claims, along with the full range of equivalents to which such claims are entitled.

As used herein, the term “or” may be construed in either an inclusive or exclusive sense. Moreover, plural instances may be provided for resources, operations, or structures described herein as a single instance. Additionally, boundaries between various resources, operations, modules, engines, and data stores are somewhat arbitrary, and particular operations are illustrated in a context of specific illustrative configurations. Other allocations of functionality are envisioned and may fall within a scope of various embodiments of the present disclosure. In general, structures and functionality presented as separate resources in the example configurations may be implemented as a combined structure or resource. Similarly, structures and functionality presented as a single resource may be implemented as separate resources. These and other variations, modifications, additions, and improvements fall within a scope of embodiments of the present disclosure as represented by the appended claims. The specification and drawings are, accordingly, to be regarded in an illustrative rather than a restrictive sense.

The foregoing description, for the purpose of explanation, has been described with reference to specific example embodiments. However, the illustrative discussions above are not intended to be exhaustive or to limit the possible example embodiments to the precise forms disclosed. Many modifications and variations are possible in view of the above teachings. The example embodiments were chosen and described in order to best explain the principles involved and their practical applications, to thereby enable others skilled in the art to best utilize the various example embodiments with various modifications as are suited to the particular use contemplated.

It will also be understood that, although the terms “first,” “second,” and so forth may be used herein to describe various elements, these elements should not be limited by these terms. These terms are only used to distinguish one element from another. For example, a first contact could be termed a second contact, and, similarly, a second contact could be termed a first contact, without departing from the scope of the present example embodiments. The first contact and the second contact are both contacts, but they are not the same contact.

The terminology used in the description of the example embodiments herein is for the purpose of describing particular example embodiments only and is not intended to be limiting. As used in the description of the example embodiments and the appended examples, the singular forms “a,” “an,” and “the” are intended to include the plural forms as well, unless the context clearly indicates otherwise. It will also be understood that the term “and/or” as used herein refers to and encompasses any and all possible combinations of one or more of the associated listed items. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

As used herein, the term “if” may be construed to mean “when” or “upon” or “in response to determining” or “in response to detecting,” depending on the context. Similarly, the phrase “if it is determined” or “if [a stated condition or event] is detected” may be construed to mean “upon determining” or “in response to determining” or “upon detecting [the stated condition or event]” or “in response to detecting [the stated condition or event],” depending on the context.

1. An electronic device, comprising:
a semiconductor die coupled to a substrate;
one or more wire bond connections from the semiconductor die to the substrate; and
one or more vertical ribbon bond connections from the semiconductor die to the substrate, wherein at least a portion of the one or more vertical ribbon bond connections is oriented with a ribbon plane orthogonal to a major plane of the substrate.

2. The electronic device of claim 1, wherein the one or more vertical ribbon bond connections is coupled to a ground voltage when in operation.

3. The electronic device of claim 1, wherein the one or more vertical ribbon bond connections includes a twist to translate a portion of the vertical ribbon bond connection from horizontal to vertical.

4. The electronic device of claim 1, wherein the one or more vertical ribbon bond connections are interspersed within a row of wire bond connections from the semiconductor die to the substrate.

5. The electronic device of claim 1, wherein vertical ribbon bond connections are included alternating between data signal wires within a row of wire bond connections from the semiconductor die to the substrate.

6. The electronic device of claim 1, wherein the semiconductor die includes a memory die.

7. The electronic device of claim 1, wherein the semiconductor die is a memory die included within a stack of memory dies.

8. The electronic device of claim 7, wherein vertical ribbon bond connections are included alternating between data signal wires within multiple rows of wire bond connections between different level dies in the stack of memory dies and the substrate.

9. An electronic device, comprising:
a stack of offset semiconductor dies coupled to a substrate;
multiple rows of wire bond connections from multiple dies in the stack of offset semiconductor dies to the substrate; and
a row of ribbon bond connections from a die in the stack of offset semiconductor dies to the substrate, wherein the row of ribbon bond connections is vertically adjacent to at least one row of wire bond connections from the multiple rows of wire bond connections.

10. The electronic device of claim 9, wherein the row of ribbon bond connections is between two different channels in the stack of offset semiconductor dies.

11. The electronic device of claim 9, wherein the row of ribbon bond connections is coupled to a ground voltage when in operation.

12. The electronic device of claim 9, wherein the row of ribbon bond connections vertically separates two rows of the multiple rows of wire bond connections.

13. The electronic device of claim 9, wherein two or more cascades of ribbon bond connections are electrically coupled together, and vertically separate two rows of the multiple rows of wire bond connections.

14. The electronic device of claim 9, further including one or more vertical ribbon bond connections from the semiconductor die to the substrate, wherein at least a portion of the one or more vertical ribbon bond connections is oriented with a ribbon plane orthogonal to a major plane of the substrate.

15. The electronic device of claim 14, wherein the vertical ribbon bond connection is on an edge of at least one row of wire bond connections from the multiple rows of wire bond connections.

16. The electronic device of claim 14, wherein at least one row of wire bond connections from the multiple rows of wire bond connections is bounded by a row of ribbon bond connections from above and below, and
wherein the at least one row of wire bond connections from the multiple rows of wire bond connections is bounded on sides by vertical ribbon bond connections.

17. A method, comprising:
attaching a first end of a bond ribbon to a first surface;
twisting the bond ribbon to orient a ribbon plane orthogonal to a major plane of the first surface to form a vertical bond ribbon;
extending a length of the vertical bond ribbon to a second surface;
twisting the bond ribbon to orient the ribbon plane parallel to a major plane of the second surface; and
attaching a second end of the bond ribbon to the second surface.

18. The method of claim 17, further including coupling the vertical bond ribbon to a ground voltage when in operation.

19. The method of claim 18, further including coupling the vertical bond ribbon laterally between two data signal bond wires.

20. The method of claim 17, further including coupling the vertical bond ribbon at a lateral edge of a row of wire bond connections, the row of wire bond connections coupled between a die and a substrate.

21. The method of claim 20, further including coupling a row of ribbon bond connections vertically adjacent to the row of wire bond connections.

22. An electronic device, comprising:
a semiconductor die coupled to a substrate;
two data wire bond connections from the semiconductor die to the substrate; and
a ground voltage vertical group of wire bond connections from the semiconductor die to the substrate, wherein the vertical group of wire bond connections both lie in a vertical plane that is oriented orthogonal to a major plane of the substrate, and wherein the vertical group of wire bond connections is between the two data wire bond connections.
